(19) United States
(12) Patent Application Publication
(10) Pub. No.: US 2025/0242455 A1
(43) Pub. Date: Jul. 31, 2025

(54) WORKTABLE SYSTEM AND MANUFACTURING METHOD OF DISPLAY PANEL USING THE SAME

(71) Applicant: Samsung Display Co., LTD., Yongin-si (KR)

(72) Inventors: Jungwoong Byun, Yongin-si (KR); MYUNGSOO HUH, Yongin-si (KR); CHEONG-WAN MIN, Yongin-si (KR); JAIHYUK CHOI, Yongin-si (KR)

(73) Assignee: Samsung Display Co., LTD., Yongin-si (KR)

(21) Appl. No.: 19/009,447

(22) Filed: Jan. 3, 2025

(30) Foreign Application Priority Data
Jan. 31, 2024 (KR) 10-2024-0015123

(51) Int. Cl. B23Q 1/34; H10K 59/12

(52) U.S. Cl. CPC B23Q 1/34; B23Q 2703/04; H10K 59/1201

(57) ABSTRACT

A worktable system includes a base stage extending in a first direction and a second direction intersecting the first direction, and having a first stroke length, and a plurality of first stages disposed on the base stage adjacent to each corner portion of the base stage, and the plurality of first stages move in the first direction and the second direction by a second stroke length that is smaller than the first stroke length.

### CROSS REFERENCE TO RELATED APPLICATION(S)

This application claims priority to and benefits of Korean Patent Application No. 10-2024-0015123 under 35 U.S.C. § 119, filed on Jan. 31, 2024, in the Korean Intellectual Property Office (KIPO), the entire contents of which are incorporated herein by reference.

### BACKGROUND

### 1. Technical Field

Embodiments relate to a worktable system. More specifically, embodiments relate to a worktable system with improved process reliability and a manufacturing method of a display panel using the worktable system.

### 2. Description of the Related Art

The significance of a display device as a medium for connecting a user and information is becoming more and more apparent as information technology advances. For example, different kinds of display devices are widely utilized in different fields. Examples of these include liquid crystal displays (“LCD”), organic light-emitting displays (“OLED”), plasma displays (“PDP”), quantum dots displays, and the like.

A display device includes a display panel including various layers on a substrate. As a size of the display device becomes more diverse, a size of the substrate also becomes more diverse. For example, the size of the substrate may vary, from a substrate forming a display panel included in a large display device such as a television to a substrate forming a display panel included in a virtual reality (“VR”) display device.

In order to improve a process reliability of forming the display panel, it is important to control precision of a worktable system supporting the substrate.

### SUMMARY

Embodiments provide a high-precision worktable system.

Embodiments provide a manufacturing method of a display panel using the worktable system.

However, embodiments are not limited to those set forth herein. The above and other embodiments will become more apparent to one of ordinary skill in the art to which the disclosure pertains by referencing the detailed description of the disclosure given below.

A worktable system according to an embodiment may include a base stage extending in a first direction and a second direction intersecting the first direction, and having a first stroke length, and a plurality of first stages disposed on the base stage adjacent to each corner portion of the base stage, and that move in the first direction and the second direction by a second stroke length that is smaller than the first stroke length.

In an embodiment, the second stroke length may be nano scale or less.

In an embodiment, the base stage may include at least one of granite, ceramic, and invar, and each of the plurality of first stages may include a first part disposed on the base stage, and including a piezo actuator; and a second part disposed on the first part, and including a porous material.

In an embodiment, a negative pressure may be provided to the second part.

In an embodiment, the worktable system may further include a second stage disposed on the base stage to be spaced apart from the plurality of first stages and including a porous material.

In an embodiment, a positive pressure may be provided to the second stage.

In an embodiment, the second stage may include a plurality of pads, and each of the plurality of pads may include a body part disposed on the base stage, including a porous material, and having an accommodating groove formed in a lower portion of the body part, and a height adjustment part disposed in the accommodating groove between the base stage and the body part, and including a handle protruding from the body part in a plan view.

In an embodiment, the plurality of pads may be arranged in a tile shape and spaced apart from each other in the first direction and the second direction.

In an embodiment, each of the plurality of pads may move up or move down in a third direction intersecting the first direction and the second direction as the height adjustment part rotates.

In an embodiment, an upper surface of the body part may be flat, and remaining surfaces of the body part except for the upper surface of the body part may be coated.

In an embodiment, a second hole may be formed in the base stage in a third direction intersecting the first direction and the second direction, the worktable system may further include a fluid passage passing through the second hole, and portion of the positive pressure may be recovered through the fluid passage.

In an embodiment, each of the plurality of pads may include a first side, a second side, a third side, and a fourth side in a plan view, and the fluid passage may include a first fluid passage adjacent to the first side, a second fluid passage adjacent to the second side, a third fluid passage adjacent to the third side, and a fourth fluid passage adjacent to the fourth side.

In an embodiment, the worktable system may further include a substrate disposed on the plurality of first stages and the second stage, and extending in the first direction and the second direction, and a sensor spaced apart from the substrate in one of the extending directions of the substrate, and measuring displacement of the substrate.

In an embodiment, a tube fitting hole may be formed in the base stage in a third direction intersecting the first direction and the second direction, and the worktable system may further include a tube passing through the tube fitting hole and connected to the second stage.

In an embodiment, a first hole may be formed in the base stage in a third direction intersecting the first direction and the second direction, the worktable system may further include a lift pin penetrating the first hole, and the lift pin may move up or move down in a third direction intersecting the first direction and the second direction.

A manufacturing method of a display panel according to an embodiment includes placing a substrate extending in a first direction and a second direction on a worktable system including a base stage extending in the first direction and the second direction intersecting the first direction and having a first stroke length, and a plurality of first stages disposed on the base stage adjacent to each corner portion of the base stage, movable in the first direction and the second direction by a second stroke length smaller than the first stroke length, and fixing the substrate by the plurality of first stages.

In an embodiment, the second stroke length may be nano scale or less.

In an embodiment, the fixing of the substrate may include providing a negative pressure to the plurality of first stages, and adsorbing the substrate by the plurality of first stages.

In an embodiment, the worktable system may further include a second stage disposed on the base stage to be spaced apart from the plurality of first stages and including a porous material, and the method may further include planarizing the substrate after the adsorbing of the substrate.

In an embodiment, the planarizing of the substrate may include providing positive pressure to the second stage.

In an embodiment, the worktable system may further include a sensor spaced apart from the substrate in one of the extending directions of the substrate and measuring displacement of the substrate, and after the adsorbing of the substrate, the method may further include measuring displacement of the substrate, and changing a position of the substrate in case that the measuring displacement of the substrate is outside a selected range.

The worktable system according to an embodiment may include a base stage extending in the first direction and the second direction and having the first stroke length, and the plurality of first stages disposed on the base stage adjacent to each corner portion of the base stage and movable by the second stroke length smaller than the first stroke length in the first direction and the second direction. By including the base stage, the long stroke length, the large-area worktable system may be implemented. For example, by including the plurality of first stages, nanoscale high-resolution may be implemented.

For example, the worktable system may further include the second stage disposed on the base stage to be spaced apart from the plurality of first stages and including the porous material. Negative pressure may be provided to the plurality of first stages, and positive pressure may be provided to the second stage. Accordingly, the substrate on the worktable system may be fixed by the plurality of first stages. For example, the effect of the friction with the second stage may be minimized.

For example, the second stage may include a plurality of pads. The plurality of pads may be spaced apart from each other in the first direction and the second direction each other in the tile form. Each of the plurality of pads may include a body part disposed on the base stage, including the porous material, and include the accommodating groove in the lower part and the height adjustment part disposed in the accommodating groove between the base stage and the body part, and including the handle that protrudes from the body part in a plan view. Each of the plurality of pads may move up or move down in the third direction as the height adjustment part rotates. Accordingly, the flatness of the substrate levitated by the positive pressure may be precisely controlled.

For example, the second hole may be formed in the base stage in the third direction. The worktable system may further include the fluid passage penetrating the second hole. Accordingly, the portion of the positive pressure provided to the substrate may be recovered to prevent pressure pooling and swelling of the substrate due to the positive pressure levitation.

For example, in an embodiment, the worktable system may further include the sensor disposed on the plurality of first stages and second stage, spaced apart from the substrate in one of the extending directions of the substrate, and measuring the displacement of the substrate. In case that the measuring displacement of the substrate is outside the predetermined range, the method may further include changing the position of the substrate in case that the measuring displacement of the substrate is outside a selected range. Accordingly, the error may be additionally compensated with high precision. For example, the method may provide small displacement that is difficult to implement with only the base stage.

### BRIEF DESCRIPTION OF THE DRAWINGS

Illustrative, non-limiting embodiments will be more clearly understood from the following detailed description taken in conjunction with the accompanying drawings.

FIG. 1 is a perspective schematic view of a worktable system according to an embodiment.

FIG. 2 is an enlarged schematic plan view of an area A of FIG. 1.

FIG. 3 is a schematic view illustrating the plurality of first stages included in the worktable system of FIG. 1.

FIG. 4 is a schematic front view of an area B of FIG. 3.

FIG. 5 is a schematic view illustrating a first hole and a second hole defined (or formed) in the worktable system of FIG. 1.

FIG. 6 is a schematic cross-sectional view taken along line I-I′ of FIG. 5.

FIGS. 7, 8, and 9 are schematic views illustrating the lift pin included in the worktable system of FIG. 1.

FIGS. 10A, 10B, and 10C are schematic views illustrating the piezo actuator included in the worktable system of FIG. 1.

FIGS. 11, 12, 13, 14, 15, and 16 are schematic views illustrating a manufacturing method of a display panel according to another embodiment.

FIG. 17 is a schematic cross-sectional view of a pixel that has been manufactured using the worktable system of FIG. 1 and the manufacturing method of the display panel of FIGS. 11, 12, 13, 14, 15, and 16.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

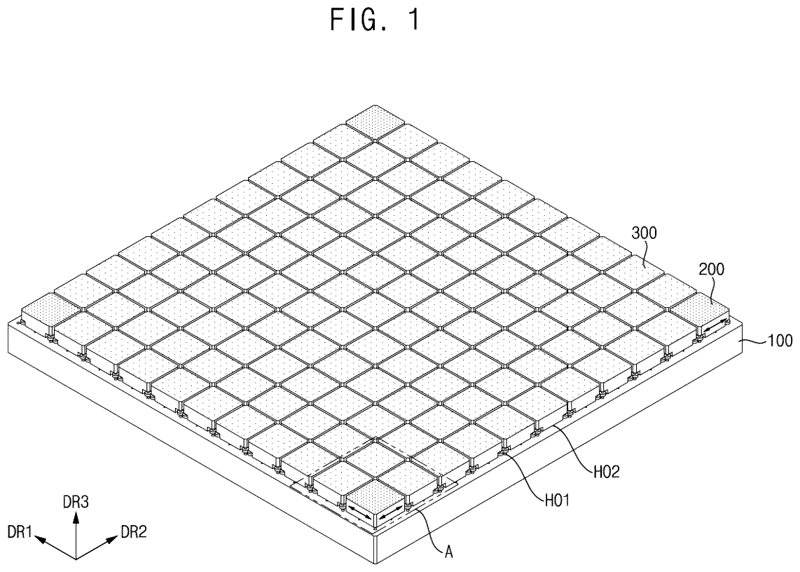

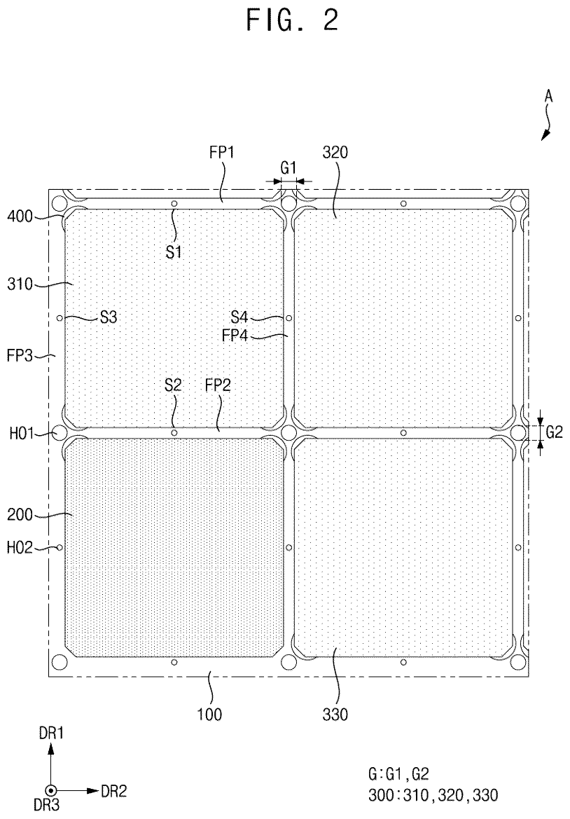

FIG. 1 is a schematic perspective view of a worktable system according to an embodiment. FIG. 2 is an enlarged schematic plan view of an area A of FIG. 1.

Referring to FIG. 1, in an embodiment, a worktable system according to an embodiment may include a base stage 100, first stages 200, and a second stage 300.

For example, the base stage 100 may be used in a manufacturing process of a display device. For example, the base stage 100 may be used in an inkjet process during the manufacturing process of the display device. For another example, the base stage 100 may be used in an exposure process during the manufacturing process of the display device. However, embodiments are not limited thereto. For example, the base stage 100 may be used in various processes that require precise control during the manufacturing process of the display device.

For example, the base stage 100 may be a long stroke length stage. For example, the base stage 100 may have a multi-layer structure. For example, a stage movable in a second direction DR2 (e.g., an upper stage) may be disposed on a stage movable in a first direction DR1 (e.g., a lower stage).

For example, the second direction DR2 may be perpendicular to the first direction DR1. However, embodiments are not limited thereto. For example, the stage movable in the first direction DR1 may be disposed on the stage movable in the second direction DR2. For another example, the base stage 100 may have a single-layer structure.

For example, a term “upper” may mean the above in a third direction DR3. For example, the third direction DR3 may be perpendicular to the first direction DR1 and the second direction DR2, respectively. Similar to what was described above, a term “lower” may mean the below in a direction opposite to the third direction DR3.

For example, the upper stage and the lower stage may include substantially same components. For example, the base stage 100 may include the base plate, a moving frame, a linear motor, a linear motor track, a linear scale, and at least one air bearing. For example, each of the upper stage and the lower stage may include the base plate, the linear motor, the linear motor track, the linear scale, and the air bearing. Hereinafter, for convenience of explanation, the description will focus on the lower stage that moves in the first direction DR1.

For example, the base plate may extend in the first direction DR1, and the second direction DR2. For example, the base plate may define a recessed space from the upper surface to the lower surface of the base plate.

In an embodiment, the base stage 100 may include granite, ceramic, invar, or the like. However, embodiments are not limited thereto. For example, the base stage 100 may include various materials.

The moving frame may be disposed on the base plate. A portion of the moving frame may be accommodated within a space of the base plate. The moving frame may be spaced apart from the base plate in the third direction DR3. The moving frame may be capable of moving in the first direction DR1 or in a direction opposite to the first direction DR1. For example, the moving frame may have a rectangular planar shape. However, embodiments are not limited thereto. For example, the moving frame may have various shapes, sizes, or the like. The linear motor may be disposed on a side of the moving frame. For example, the linear motor may be disposed on opposite sides of the moving frame. The linear motor may be fixed to the moving frame. For example, the linear motor may include a coil.

The linear motor track may be disposed on the base plate. The linear motor track may extend in the first direction DR1. The linear motor track may define a space in which a portion of the linear motor may be accommodated. The linear motor track may not be in contact with the linear motor. For example, the linear motor track and the linear motor may be spaced apart from each other. For example, the linear motor track may include a magnet.

The linear motor may be capable of moving in the first direction DR1 or in the direction opposite to the first direction DR1 along the linear motor track. For example, the linear motor and the linear motor track may move the moving frame. For example, the linear motor and the linear motor track may move the moving frame using electromagnetic force. The moving frame may be capable of moving in the first direction DR1 or in the direction opposite to the first direction DR1 by the linear motor and the linear motor track. For example, the moving frame may move in a straight line by the linear motor and the linear motor track.

The linear scale (or encoder) may be disposed on the base plate. For example, the linear scale may be disposed below the moving frame. The linear scale may extend in the first direction DR1. The linear scale may detect information such as a position, moving distance, and moving speed of the linear motor. For example, the linear scale may provide feedback the information.

The air bearing may be disposed on the side of the moving frame. For example, the air bearing may be disposed on a bottom and/or a side of the moving frame. For example, the air bearing may be fixed to the moving frame within the space defined by the base plate. For example, the air bearing may discharge air to levitate the moving frame from the base plate.

However, embodiments are not limited thereto. For example, the base stage 100 may include one, two, three, five or more air bearing(s). For another example, the base stage 100 may further include other components, or some of the components may be omitted.

In an embodiment, the first stages 200 may be arranged on the base stage 100 and may be adjacent to each corner portion of the base stage 100.

In an embodiment, the base stage 100 may have a first stroke length, and each of the first stages 200 may have a second stroke length that is smaller than the first stroke length. As described above, for example, the base stage 100 may be the large stroke length stage, and each of the first stages 200 may be a relatively small stroke length stage.

In a case of the worktable system according to a comparative example, the worktable system may include only the large stroke length stage or the small stroke length stage.

For example, in the case of the worktable system including only the large stroke length stage, it may be difficult to implement nanoscale micro-displacement or high precision. For example, for a worktable system with a stroke length of about a few thousand millimeters (mm), compensation precision may be only about a few microns (1/1000 m). Accordingly, it may be difficult to use in the manufacturing process of the display device that requires great precision.

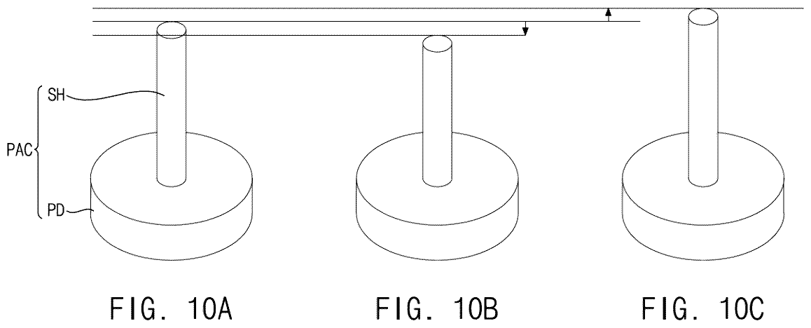

In the case of the worktable system including only the small stroke length stage, it may be difficult to manufacture in a large area. For example, the small stroke length stage may include a piezo actuator (e.g., see FIGS. 10A, 10B, and 10C) and a flexure motion guide (e.g., flexure hinge). For example, the flexure motion guide may refer to a displacement amplifier that readily generates parasitic motion. For example, the flexure motion guide may amplify an angstrom ((2) unit movement of the piezo actuator into micro to nano unit movement. However, the flexure motion guide may be difficult to manufacture in the large area due to design difficulties.

The worktable system according to an embodiment may have a structure in which the first stages 200 are arranged on the base stage 100. The base stage 100 may have the first stroke length, and each of the first stages 200 may have the second stroke length that is smaller than the first stroke length. In an embodiment, the second stroke length may be nano scale or less. Accordingly, unlike the worktable systems according to the comparative example, a large-stroke length, large-area, and high-precision worktable system may be implemented. For example, it may move about several meters (m) by the base stage 100, it may move about several millimeters (mm) by the first stages 200, and the first stages 200 may be compensated an error about several nanometers (nm).

For example, a translational motion error (e.g., flatness error, straightness error, or the like.) may occur along an axis parallel to each of the first direction DR1, the second direction DR2, and/or the third direction DR3. For another example, a rotational motion error (e.g., yaw error, roll error, pitch error, or the like.) may occur along an axis parallel to each of the first direction DR1, the second direction DR2 and/or the third direction DR3.

In an embodiment, the second stage 300 may be disposed on the base stage 100 to be spaced apart from the first stages 200 by a gap G (e.g., G1 and G2 of FIG. 2).

In an embodiment, the second stage 300 may include pads (e.g., 310, 320, and 330 of FIG. 2). For example, the second stage 300 may include a first pad 310, a second pad 320, and a third pad 330. For example, the first pad 310 may be disposed on the base stage 100 to be spaced apart from any one of the first stages 200 in the first direction DR1, e.g., by a second gap G2. The third pad 330 may be disposed on the base stage 100 to be spaced apart from any one of the first stages 200 in the second direction DR2, e.g., by a first gap G1. The second pad 320 may be disposed on the base stage 100 to be spaced apart from any one of the first stages 200 in a direction between the first direction DR1 and the second direction DR2.

In an embodiment, the pads may be spaced apart from each other in the first direction DR1, e.g., by the second gap G2 and/or the second direction DR2, e.g., by the first gap G1, and arranged in a tile shape. For example, the first pad 310 and the second pad 320 may be arranged to be spaced apart from each other in the second direction DR2, e.g., by the first gap G1. The second pad 320 and the third pad 330 may be arranged to be spaced apart from each other in the first direction DR1, e.g., by the second gap G2. For example, the pads may be repeatedly arranged to be spaced apart from each other along the first direction DR1, and the pads may be repeatedly arranged to be spaced apart from each other along the second direction DR2.

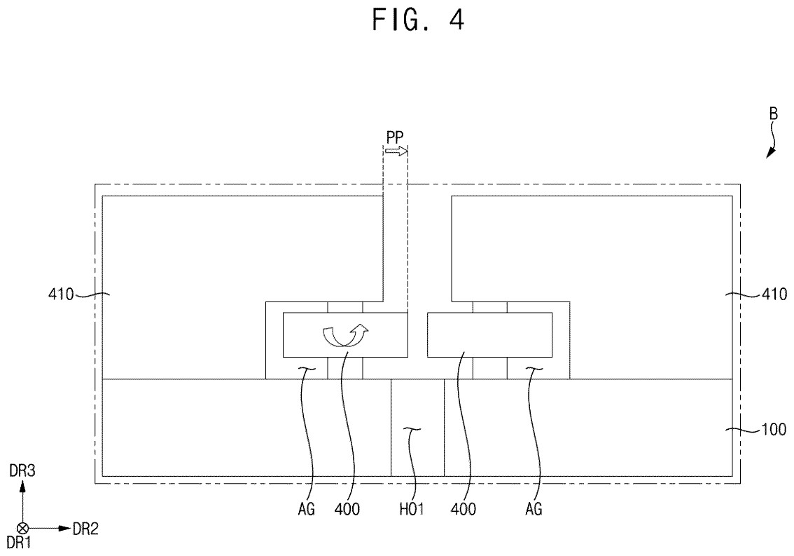

In an embodiment, a positive pressure, which is caused by, e.g., air released in the third direction DR3, may be provided to the second stage 300. In an embodiment, the second stage 300 may include a porous material. In an embodiment, the porous material may be included in the body part (e.g., 410 of FIG. 4) included in the second stage 300.

For example, the porous material may include metal. For example, the porous material may be formed by controlling (or adjusting) a porosity of alumina. However, embodiments are not limited thereto.

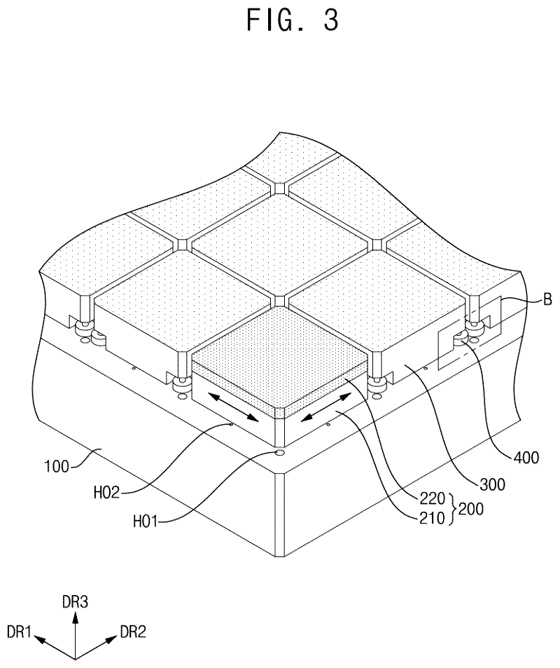

FIG. 3 is a schematic view illustrating the first stages included in the worktable system of FIG. 1. FIG. 4 is a schematic front view of an area B of FIG. 3.

With reference to FIGS. 3 and 4, the first stages 200 and second stages 300 will be described in more detail.

Referring to FIGS. 1, 2, and 3, in an embodiment, each of the first stages 200 may include a first part 210 and a second part 220.

In an embodiment, the first part 210 may be disposed on the base stage 100 and may include a piezo actuator (e.g., see FIGS. 10A, 10B, and 10C). As described above, the piezo actuator may have various structures, shapes, arrangements, or the like.

In an embodiment, the second part 220 may be disposed on the first part 210. In an embodiment, a negative pressure, which is caused by the air flowing in the direction opposite to the third direction DR3, may be provided to the second part 220. In an embodiment, the second part 220 may include a porous material.

For example, the porous material may include metal. For example, the porous material may be formed by controlling (or adjusting) the porosity of alumina. However, embodiments are not limited thereto.

For example, the porous material included in the first stages 200 and the second stage 300 may have of a same type. However, embodiments are not limited thereto. For example, the porous materials included in the first stages 200 and the second stage 300 may have different types.

Referring to FIGS. 1, 2, and 4, in an embodiment, the second stage 300 may include pads (e.g., a first pad 310, a second pad 320, and a third pad 330 of FIG. 2). In an embodiment, each of the pads may include a body part 410 and a height adjustment part 400.

In an embodiment, the body part 410 may be disposed on the base stage 100 and an accommodating groove AG may be defined (or formed) in a lower portion.

In an embodiment, the body part 410 may include the porous material. For example, the porous material may function the air to freely enter and exit (or to freely flow) through the pores, so that remaining surfaces except for an upper surface (e.g., a lower surface facing the upper surface in the direction opposite to the third direction DR3, and side surfaces crossing each of the upper surface and the lower surface) of the body part 410 may be coated.

In an embodiment, the height adjustment part 400 may be disposed in the accommodating groove AG between the base stage 100 and the body part 410. For example, the accommodating groove AG may define a space in which the height adjustment part 400 is disposed.

As shown in FIGS. 2 and 4, in an embodiment, when viewed on a plane defined by the first direction DR1 and the second direction DR2 (or in a plan view), the height adjustment part 400 may have may include a handle (or knob) protruding from the body part 410 (see 310, 320, and 330 of FIG. 2). For example, the handle may protrude a selected length PP from an end portion of the body part 410. Accordingly, the handle may be turned clockwise or counterclockwise from an outside.

In an embodiment, each of the pads may move up in the third direction DR3 or may move down in the direction opposite to the third direction DR3 as the height adjustment part rotates.

For example, the height adjustment part 400 may include a leveling adjustment bolt. The second stage 300 may be lifted only by the leveling adjustment bolt. For example, the second stage 300 may not interfere with the base stage 100.

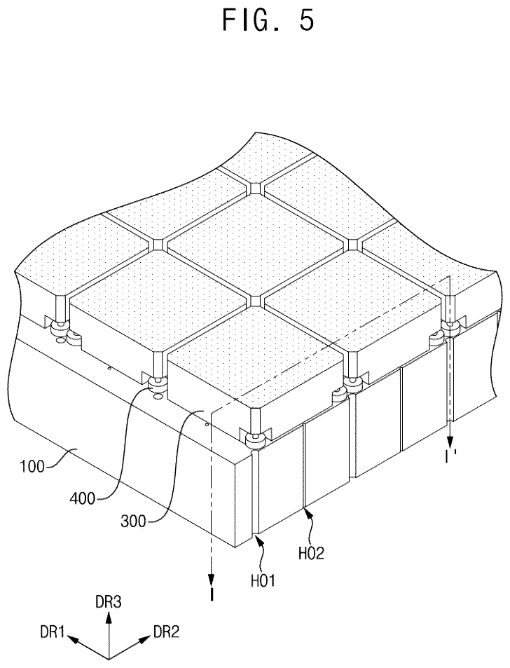

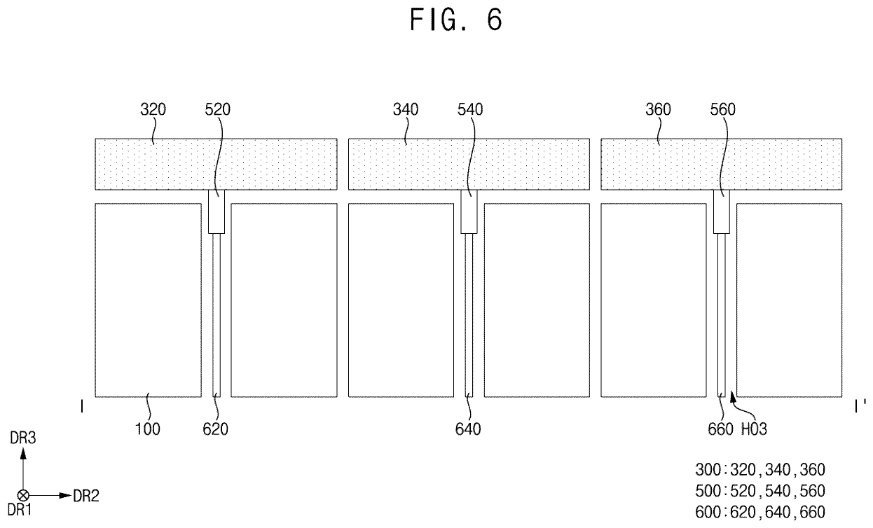

FIG. 5 is a schematic view illustrating a first hole and a second hole defined (or formed) in the worktable system of FIG. 1. FIG. 6 is a schematic cross-sectional view taken along line I-I′ of FIG. 5.

Referring to FIGS. 1, 2, 3, 4, 5, and 6, in an embodiment, a tube fitting hole H03 may be defined (or formed) in the base stage 100 in the third direction DR3.

In an embodiment, the second stage 300 may be connected to a tube 600 disposed in the tube fitting hole H03. The tube 600 may be connected to a pump, or the like.

In an embodiment, the second stage 300 may include the pads (e.g., the second pad 320, the fourth pad 340, and the sixth pad 360). Each of the pads may be individually connected to the pump, or the like. For example, the second pad 320 may be connected to a first tube 620 through a fitting portion 500 (e.g., a first fitting portion 520). The fourth pad 340 may be connected to a second tube 640 through the fitting portion 500 (e.g., a second fitting portion 540). The sixth pad 360 may be connected to a third tube 660 through the fitting portion 500 (e.g., a third fitting portion 560). However, embodiments are not limited thereto. For example, when the base stage 100 includes metal, each of a first tube 620, a second tube 640, and a third tube 660 may be connected to the metal by welding. For example, the fitting portion (e.g., the first fitting portion 520, the second fitting portion 540, and the third fitting portion 560) connecting the tube 600 and the second stage 300 may be omitted.

The tube 600 may be connected only to the second stage 300 and may not interfere with the base stage 100.

Referring again to FIGS. 1, 2, 3, 4, and 5, in an embodiment, a first hole H01 and a second hole H02 may be defined (or formed) in the base stage 100. Each of the first hole H01 and the second hole H02 may pass through the base stage 100 in the third direction DR3.

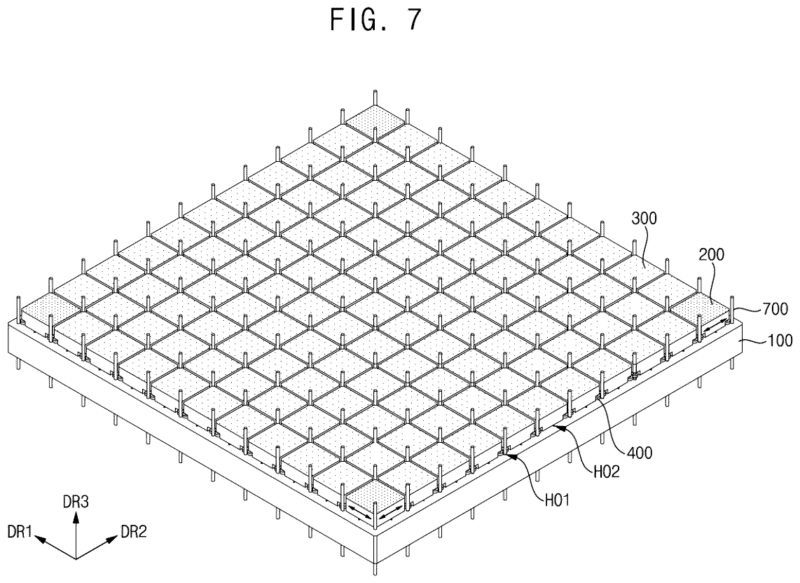

For example, the first hole H01 may be a hole for defining a space where a lift pin (e.g., a lift pin 700 in FIG. 7) is disposed, and the second hole H02 may be a hole for defining a fluid passage (e.g., a space where the pipe, through which the positive pressure is recovered, is placed). The fluid passage may overlap the second hole H02 on the plane.

As shown in FIG. 2, in an embodiment, each of the pads on the plane may include a first side S1, a second side S2, a third side S3, and a fourth side S4. For example, the fluid passage may include a first fluid passage FP1 adjacent to the first side S1, a second fluid passage FP2 adjacent to the second side S2, a third fluid passage FP3 adjacent to the third side S3, and a fourth fluid passage FP4 adjacent to the fourth side S4. However, embodiments are not limited thereto. For example, two or more fluid passages may be arranged adjacent to each side of the pads. For example, the fluid passage may further include a fifth fluid passage adjacent to the first side S1, a sixth fluid passage adjacent to the second side S2, a seventh fluid passage adjacent to the third side S3, and an eighth fluid passage adjacent to the fourth side S4.

For example, a pot-bellied phenomenon may occur in the substrate due to the positive pressure. The pot-bellied phenomenon may mean a state in which the levels of a center portion of the substrate and an edge portion of the substrate are different. The edge portion may surround the center.

To prevent the pot-bellied phenomenon (or to improve flatness of the substrate), the fluid passage may recover part (or reclaim some) of the positive pressure. Accordingly, air at a constant flow rate may be provided to each of the pads.

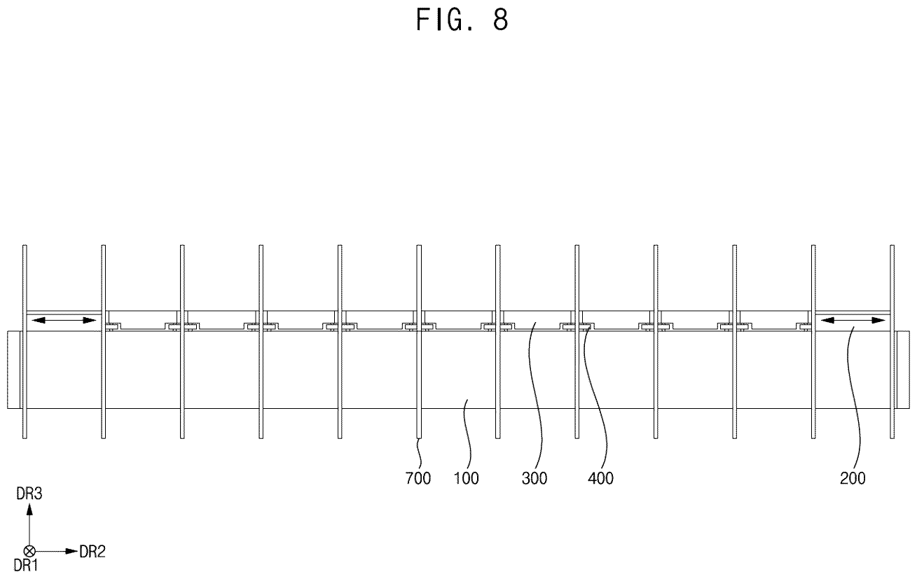

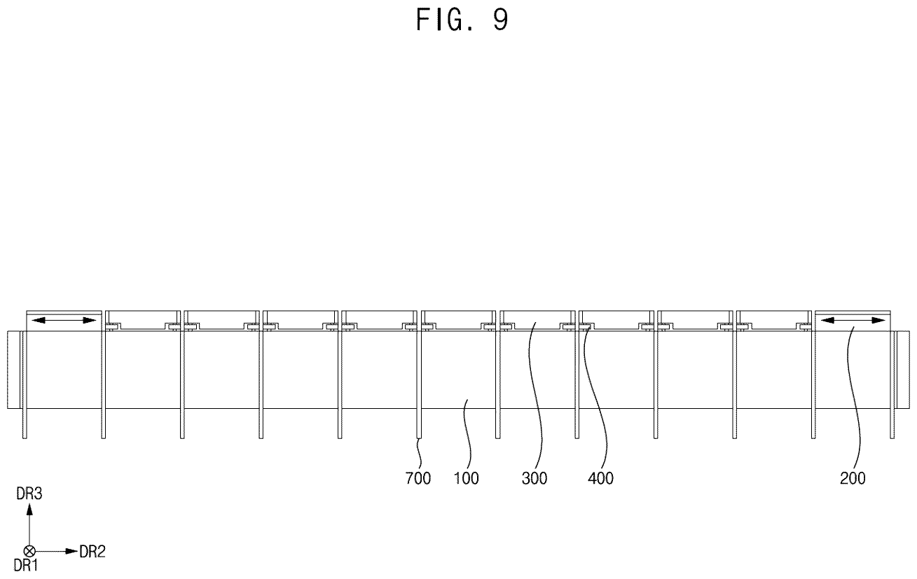

FIGS. 7, 8, and 9 are schematic views illustrating the lift pin included in the worktable system of FIG. 1. For example, FIG. 7 is a schematic perspective view of the lift pin. FIGS. 8 and 9 are a schematic cross-sectional view with the lift pin raised and a schematic cross-sectional view with the lift pin lowered, respectively.

Referring to FIGS. 7, 8, and 9, in an embodiment, the lift pin 700 may penetrate the first hole H01. In an embodiment, the lift pin 700 may move up and down in the third direction DR3. In another example, the lift pin 700 may descend in the direction opposite to the third direction DR3.

FIGS. 10A, 10B, and 10C are schematic views illustrating the piezo actuator included in the worktable system of FIG. 1.

Referring to FIGS. 1, 10A, 10B, and 10C, each of the first stages 200 may include a piezo actuator PAC. The piezo actuator PAC may have high control precision and fast response times. For example, the piezo actuator PAC may include a piezoelectric element PD and a shaft SH. For example, when voltage is applied to the piezoelectric element PD and expands, a level of an upper surface may change as the shaft SH rotates. When fully expanded, the shaft may return to its initial position by contracting quickly. However, this is an example, and the piezo actuator PAC may have various structures, arrangements, or the like.

The worktable system described above with reference to FIGS. 1, 2, 3, 4, 5, 6, 7, 8, 9, and 10 is an example, and the worktable system according to an embodiment may further include various components.

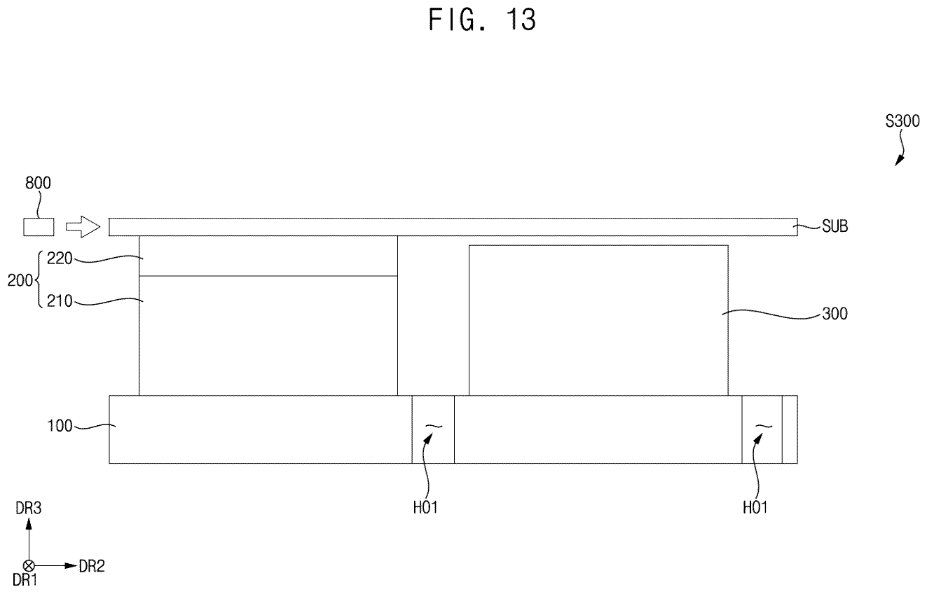

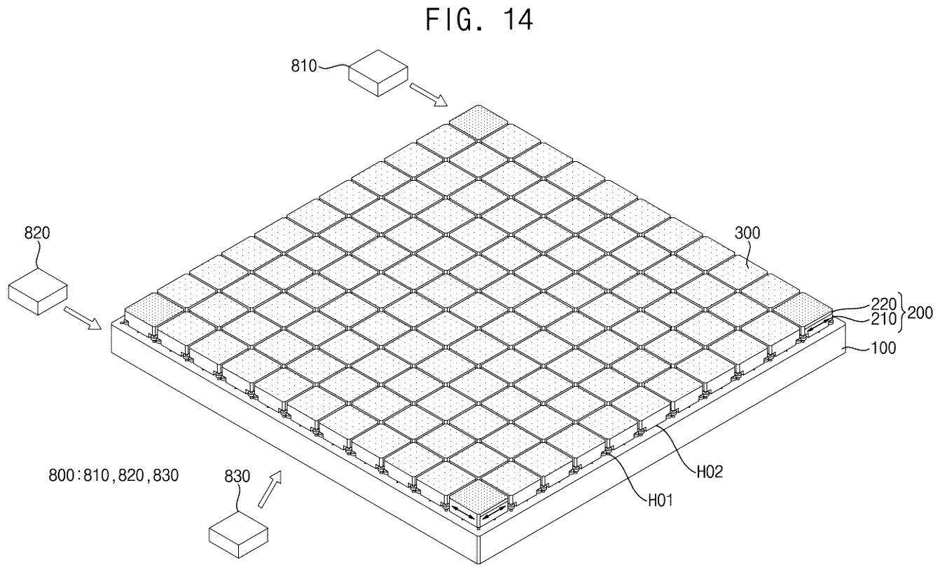

In an embodiment, the worktable system may further include a sensor (e.g., see 800 of FIGS. 13 and 14) that measures the displacement of the substrate.

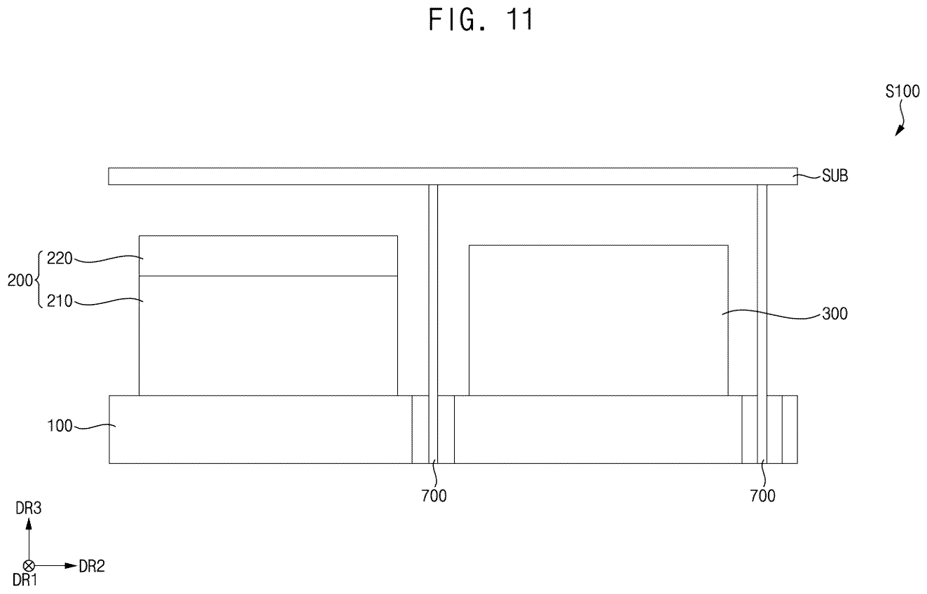

In an embodiment, a substrate (e.g., a substrate SUB of FIG. 11) may be disposed on the first stages 200 and the second stage 300. In an embodiment, the substrate may extend in the first direction DR1 and the second direction DR2. A processing process (e.g., ink ejection, exposure, or the like) for manufacturing the display device may be performed on the substrate.

In an embodiment, the sensor may be arranged to be spaced apart from the substrate in one of the extending directions of the substrate SUB (e.g., the first direction DR1 or the second direction DR2).

A detailed description of the sensor will be described below with reference to FIG. 14.

For example, the translational motion error and/or the rotational motion error may occur during the process of manufacturing the display device. For example, the linear scale included in the base stage 100 may detect the translational motion error and provide feedback.

In the case of the worktable system according to the comparative example that includes only the linear scale, the feedback may be inaccurate because a distance from the linear scale to the substrate on the worktable system is large. For example, a treatment process may be performed in an unintended area of the substrate. Accordingly, a defect (e.g., a dark spot, mixed colors, or the like) may occur in the display device, or display quality may deteriorate.

However, the worktable system according to an embodiment may further include the sensor (e.g., 800 of FIGS. 13 and 14). The sensor may detect and feedback the information such as the location of the moving frame. For example, the sensor may detect and feedback the translational motion error and/or the rotational motion error. Accordingly, process reliability may be improved and the display quality of the display device may be improved.

As described above, the worktable system according to an embodiment may include a base stage 100 extending in the first direction DR1 and the second direction DR2 and having the first stroke length, and the first stages 200 disposed on the base stage 100 adjacent to each corner portion of the base stage 100 and movable by the second stroke length smaller than the first stroke length in the first direction DR1 and the second direction DR2. The long stroke length, the large-area worktable system may be implemented by providing the base stage 100. For example, nanoscale high-resolution may be implemented by providing the first stages 200.

For example, the worktable system may further include the second stage 300 disposed on the base stage 100 to be spaced apart from the first stages 200 and including the porous material. Negative pressure may be provided to the first stages 200, and positive pressure may be provided to the second stage 300. Accordingly, the substrate on the worktable system may be fixed by the first stages 200. For example, the effect of the friction with the second stage 300 may be minimized.

For example, the second stage 300 may include pads (e.g., the first pad 310, the second pad 320, and the third pad 330). The pads may be spaced apart from each other in the first direction DR1 and the second direction DR2 in the tile form. Each of the pads may include a body part 410 disposed on the base stage 100, including the porous material, and defined the accommodating groove AG in the lower part, and the height adjustment part 400 disposed in the accommodating groove AG between the base stage 100 and the body part 410, and including the handle that protrudes from the body part 410 when viewed on the plane defined by the first direction DR1 and the second direction DR2. Each of the pads may move up or move down in the third direction DR3 as the height adjustment part 400 rotates. Accordingly, the flatness of the substrate levitated by the positive pressure may be precisely controlled.

For example, the second hole H02 may be defined (or formed) in the base stage 100 in the third direction DR3. The worktable system may further include the fluid passage penetrating the second hole H02. Accordingly, the portion of the positive pressure provided to the substrate may be recovered to prevent pressure pooling and swelling of the substrate due to the positive pressure levitation.

For example, in an embodiment, the worktable system may further include the sensor (e.g., 800 of FIGS. 13 and 14) disposed on the first stages 200 and second stage 300, disposed to be spaced apart from the substrate in one of the extending directions of the substrate, and measuring the displacement of the substrate. When the measuring displacement of the substrate is outside the selected range, the method may further include changing the position of the substrate when the measuring displacement of the substrate is outside a selected range. Accordingly, the error may be additionally compensated with high precision. For example, the method may provide small displacement that is difficult to implement with only the base stage 100.

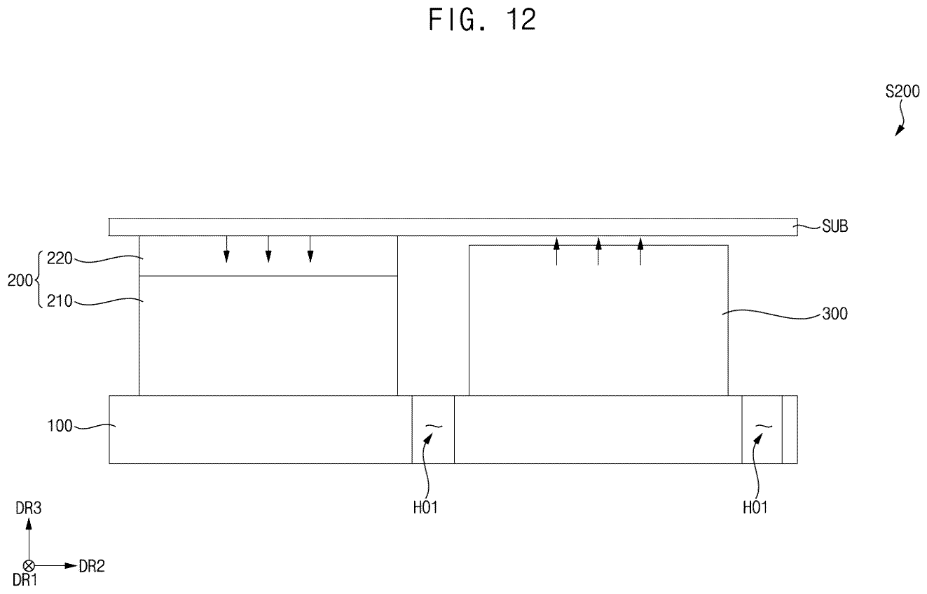

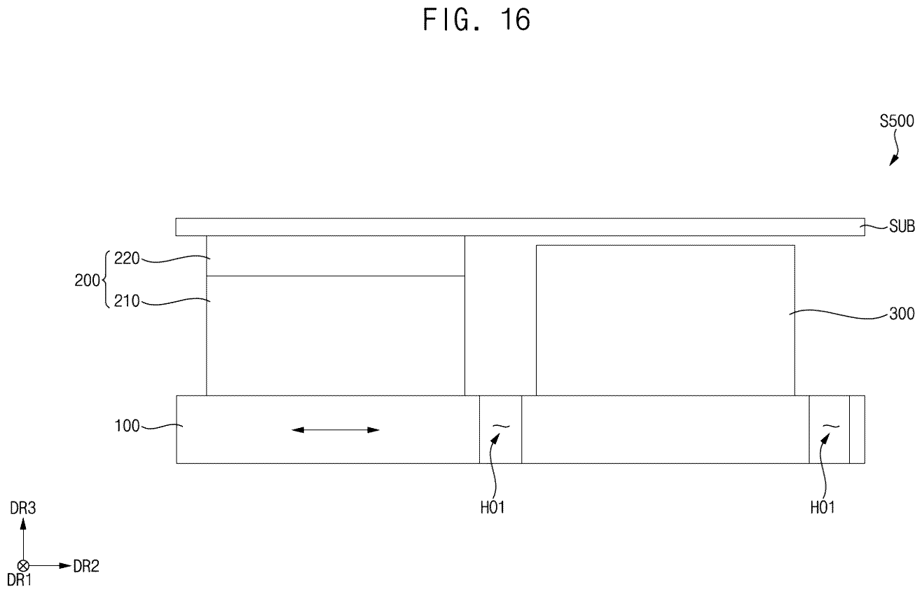

FIGS. 11, 12, 13, 14, 15, and 16 are schematic views illustrating a manufacturing method of a display panel according to another embodiment.

The manufacturing method of the display panel described with reference to FIGS. 11, 12, 13, 14, 15, and 16 may use the worktable system according to an embodiment described above with reference to FIGS. 1, 2, 3, 4, 5, 6, 7, 8, 9, and 10. Therefore, hereinafter, overlapping descriptions of the worktable system according to an embodiment will be omitted or simplified.

The manufacturing method of the display panel according to an embodiment may include the following steps. Referring to FIGS. 1, 11, and 12, in an embodiment, the substrate SUB may be disposed on the worktable system (S100) and the first stages 200 may be fixed on the substrate SUB (S200).

For example, the substrate SUB may be supported (or disposed) by the lift pin 700 penetrating the base stage 100.

In an embodiment, the step of fixing the substrate SUB may further include providing negative pressure to the first stages 200 and adsorbing the substrate SUB by the first stages 200, and flattening the substrate SUB. In an embodiment, flattening the substrate SUB may include providing positive pressure to the second stage.

Accordingly, the substrate SUB may be fixed by the first stages 200 and may not be shaken while the processing process is performed. For example, the effect of friction with the second stage 300 may be minimized.

Referring to FIGS. 13 and 14, in an embodiment, the displacement of the substrate SUB may be measured (S300).

For example, the worktable system may have sensors 800. For example, the worktable system may include a first sensor 810, a second sensor 820, and a third sensor 830.

For example, two sensors 800 may be arranged in a direction parallel to the moving direction of the worktable system and one sensor may be arranged in a direction intersecting the moving direction of the worktable system.

For example, as depicted in FIG. 14, the base stage 100 included in the worktable system may move along the second direction DR2. For example, the first sensor 810 and the second sensor 820 may be arranged in the direction parallel to the moving direction, and the third sensor 830 may be arranged in a direction intersecting the moving direction.

For example, the first sensor 810 and the second sensor 820 may be disposed at opposite end portions of the worktable system. The third sensor 830 may be arranged to enter and retreat in the direction intersecting the moving direction. Accordingly, X-axis data, Y-axis data, and Z-axis data may be secured or ensured.

For example, the sensor 800 may be an interferometer system. The interferometer may measure the movement of the worktable system by installing a reflective mirror on the worktable system, irradiating a laser to the reflective mirror, and measuring the change in wave frequency of light reflected and returned by the reflective mirror. (e.g., Doppler effect).

For example, the reflective mirror may be disposed on a side of the first part 210 included in the first stages 200. As described above, the first part 210 may correspond to a mover.

For example, the sensor 800 may be disposed adjacent to the worktable system. For example, in case that other components exist on the path through which the laser beam is emitted and received, measurement errors may occur due to interference with the components, and collisions with the components may cause the mirror and/or the sensor 800 may be damaged. For example, the sensor 800 may be disposed adjacent to the worktable system to prevent the problems.

However, this is an example, and embodiments are not limited thereto. For example, the number of sensors 800 may vary. For example, considering the stroke length of the worktable system, there may be four or more sensors 800. For another example, there may be one or two sensors 800.

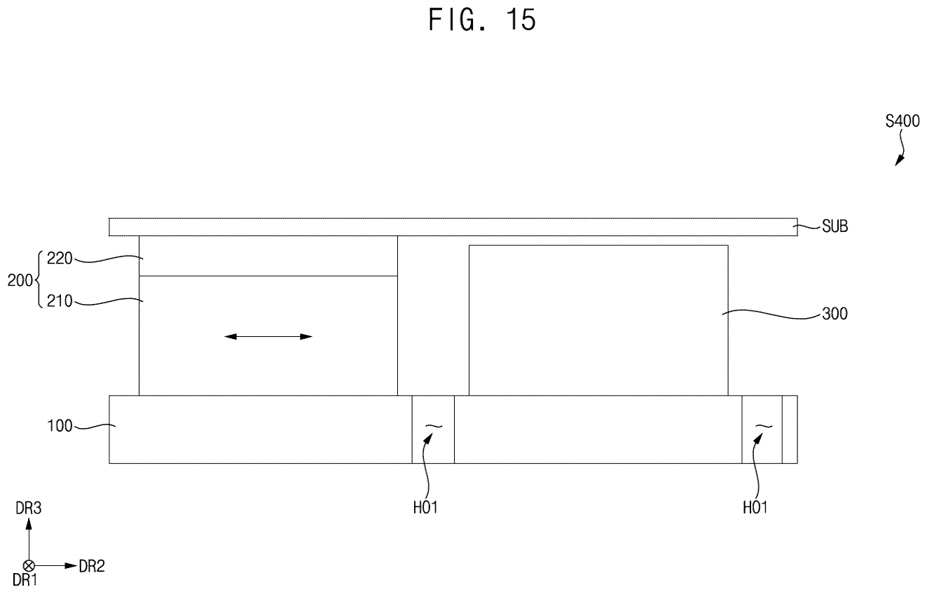

Referring to FIG. 15, in an embodiment, in case that the measuring displacement of the substrate SUB is outside the selected range, the position of the substrate SUB may be changed (S400). For example, by including the base stage 100, the long stroke length, the large-area worktable system may be implemented (S500). For example, by including the first stages 200, nanoscale high-resolution may be implemented, and the substrate SUB may be moved by a small displacement (S400).

In case that the measuring displacement of the substrate SUB is outside the selected range, the step of changing the position of the substrate SUB may be further included. Accordingly, the error may be additionally compensated for with high precision. For example, it may move by the small displacement that is difficult to implement with the base stage 100.

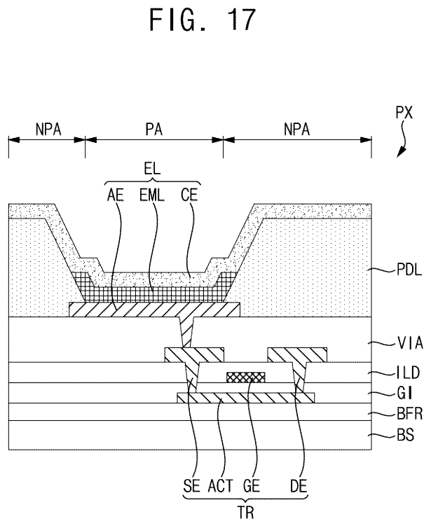

FIG. 17 is a schematic cross-sectional view of a pixel that has been manufactured using the worktable system of FIG. 1 and the manufacturing method of the display panel of FIGS. 11, 12, 13, 14, 15, and 16.

Referring to FIG. 17, the pixel PX may include a base substrate BS, a buffer layer BFR, a transistor TR, a gate insulating layer GI, an interlayer insulating layer ILD, a via insulating layer VIA, a light emitting element EL, and a pixel defining layer PDL. The transistor may include an active layer ACT, a gate electrode GE, a source electrode SE, and a drain electrode DE. The light emitting element EL may include a first electrode AE, a light emitting layer EML, and a second electrode CE. The display area may include a light emission area PA and a non-emission area NPA. The transistor TR and the light emitting element EL may be disposed in the light emission area PA. The non-emission area NPA may surround the light emission area PA in a plan view. Here, plan view may mean when viewed in the first direction DR1.

The base substrate BS may include glass, quartz, plastic, or the like. In an embodiment, the base substrate BS may have flexible, bendable, or rollable characteristics.

The buffer layer BFR may be disposed on the base substrate BS. The buffer layer BFR may include an inorganic insulating material. For example, the buffer layer BFR may include silicon oxide, silicon nitride, silicon oxynitride, or the like. The buffer layer BFR may function to block impurities so that the active layer ACT of the transistor TR may not be damaged by the impurities diffused from the base substrate BS.

The active layer ACT may be disposed on the buffer layer BFR. In an embodiment, the active layer ACT may include a silicon semiconductor. For example, the active layer ACT may include amorphous silicon or polycrystalline silicon. In another embodiment, the active layer ACT may include an oxide semiconductor. For example, the active layer ACT may include zinc oxide, zinc-tin oxide, zinc-indium oxide, indium oxide, titanium oxide, indium-gallium-zinc oxide, indium-zinc-tin oxide, or the like.

The gate insulating layer GI may be disposed on the active layer ACT. The gate insulating layer GI may include an inorganic insulating material. For example, the gate insulating layer GI may include silicon oxide, silicon nitride, silicon oxynitride, titanium oxide, tantalum oxide, or the like. The gate insulating layer GI may function to electrically insulate the active layer ACT and the gate electrode GE from each other.

The gate electrode GE may be disposed on the gate insulating layer GI. The gate electrode GE may include a conductive material. For example, the gate electrode GE may include a metal, an alloy, a conductive metal oxide, a transparent conductive material, or the like. A gate signal may be applied to the gate electrode GE. The gate signal may turn on or turn off the transistor TR to adjust electrical conductivity of the active layer ACT.

The interlayer insulating layer ILD may be disposed on the gate electrode GE. The interlayer insulating layer ILD may include an organic insulating material and/or an inorganic insulating material. The interlayer insulating layer ILD may function to electrically insulate the source electrode SE and drain electrode DE from the gate electrode GE.

The source electrode SE and the drain electrode DE may be disposed on the interlayer insulating layer ILD. Each of the source electrode SE and the drain electrode DE may include a conductive material. For example, each of the source electrode SE and the drain electrode DE may include a metal, an alloy, a conductive metal oxide, a transparent conductive material, or the like. Each of the source electrode SE and the drain electrode DE may electrically contact the active layer ACT through a contact hole passing through the interlayer insulating layer ILD and the gate insulating layer GI.

The via insulating layer VIA may be disposed on the source electrode SE and the drain electrode DE. The via insulating layer VIA may include an organic insulating material. For example, the via insulating layer VIA may include a poly-acrylic resin, a polyimide resin, an acrylic resin, or the like. Accordingly, a top surface of the via insulating layer VIA may be substantially flat.

The first electrode AE may be disposed on the via insulating layer VIA. The first electrode AE may include a conductive material. For example, the first electrode AE may include a metal, an alloy, a conductive metal oxide, a transparent conductive material, or the like. The first electrode AE may electrically contact the source electrode SE or the drain electrode DE through a contact hole penetrating the via insulating layer VIA. In an embodiment, the first electrode AE may be referred to as an anode electrode.

The pixel defining layer PDL may be disposed on the first electrode AE. The pixel defining layer PDL may include an organic insulating material. For example, the pixel defining layer PDL may include a polyacryl-based compound or a polyimide-based compound. The pixel defining layer PDL may partition (or define) the light emission area PA of each of the pixels PX. The pixel defining layer PDL may include a pixel opening exposing the first electrode AE.

The light emitting layer EML may be disposed on the first electrode AE in the pixel opening. The light emitting layer EML may include an organic light emitting material. In an embodiment, the light emitting layer EML may have a multi-layer structure including various functional layers. In an embodiment, the light emitting layer EML may include at least one of a hole injection layer, a hole transport layer, an electron transport layer, and an electron injection layer.

The second electrode CE may be disposed on the light emitting layer EML and may cover the pixel defining layer PDL. In an embodiment, the second electrode CE may be referred to as a cathode electrode.

In an embodiment, the light emitting layer EML may be formed by depositing deposition materials on the first electrode AE. The worktable system (e.g., the worktable system of FIG. 1) may be used.

However, embodiments are not limited thereto, and the worktable system may be used in various processes that require positioning and movement of the substrate (e.g., the base substrate BS of FIG. 17 or the substrate of FIGS. 11, 12, 13, 15, and 16).

The worktable system according to embodiments may be applied to a process of manufacturing a display device included in a computer, laptop, mobile phone, smart phone, smart pad, PMP, PDA, MP3 player, and the like.

The above description is an example of technical features of the disclosure, and those skilled in the art to which the disclosure pertains will be able to make various modifications and variations. Therefore, the embodiments described above may be implemented separately or in combination with each other.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A worktable system comprising:
a base stage extending in a first direction and a second direction intersecting the first direction, and having a first stroke length; and
a plurality of first stages disposed on the base stage adjacent to each corner portion of the base stage, the plurality of first stages that move in the first direction and the second direction by a second stroke length that is smaller than the first stroke length.

2. The worktable system of claim 1, wherein the second stroke length is nano scale or less.

3. The worktable system of claim 1, wherein,
the base stage includes at least one of granite, ceramic, and invar, and
each of the plurality of first stages includes:
a first part disposed on the base stage, and including a piezo actuator; and
a second part disposed on the first part, and including a porous material.

4. The worktable system of claim 3, wherein a negative pressure is provided to the second part.

5. The worktable system of claim 1, further comprising:
a second stage disposed on the base stage to be spaced apart from the plurality of first stages, the second stage including a porous material.

6. The worktable system of claim 5, wherein a positive pressure is provided to the second stage.

7. The worktable system of claim 6, wherein,
the second stage includes a plurality of pads, and
each of the plurality of pads includes:
a body part disposed on the base stage, including a porous material, and having an accommodating groove formed in a lower portion of the body part; and
a height adjustment part disposed in the accommodating groove between the base stage and the body part, and including a handle protruding from the body part in a plan view.

8. The worktable system of claim 7, wherein the plurality of pads are arranged in a tile shape and spaced apart from each other in the first direction and the second direction.

9. The worktable system of claim 7, wherein each of the plurality of pads moves up or moves down in a third direction intersecting the first direction and the second direction as the height adjustment part rotates.

10. The worktable system of claim 7, wherein,
an upper surface of the body part is flat, and
remaining surfaces of the body part except for the upper surface of the body part are coated.

11. The worktable system of claim 7, wherein
a second hole is formed in the base stage in a third direction intersecting the first direction and the second direction,
the worktable system further comprises a fluid passage passing through the second hole, and
a portion of the positive pressure is recovered through the fluid passage.

12. The worktable system of claim 11, wherein,
each of the plurality of pads includes a first side, a second side, a third side, and a fourth side in a plan view, and
the fluid passage includes a first fluid passage adjacent to the first side, a second fluid passage adjacent to the second side, a third fluid passage adjacent to the third side, and a fourth fluid passage adjacent to the fourth side.

13. The worktable system of claim 5, further comprising:
a substrate disposed on the plurality of first stages and the second stage, and extending in the first direction and the second direction; and
a sensor spaced apart from the substrate in one of the extending directions of the substrate, the sensor that measures displacement of the substrate.

14. The worktable system of claim 5, wherein
a tube fitting hole is formed in the base stage in a third direction intersecting the first direction and the second direction, and
the worktable system further comprises a tube passing through the tube fitting hole and connected to the second stage.

15. The worktable system of claim 5, wherein
a first hole is formed in the base stage in a third direction intersecting the first direction and the second direction,
the worktable system further comprises a lift pin penetrating the first hole, and
the lift pin moves up or moves down in a third direction intersecting the first direction and the second direction.

16. A manufacturing method of a display panel, the method comprising:
placing a substrate extending in a first direction and a second direction on a worktable system including a base stage extending in the first direction and the second direction intersecting the first direction and having a first stroke length, and a plurality of first stages disposed on the base stage adjacent to each corner portion of the base stage, movable in the first direction and the second direction by a second stroke length smaller than the first stroke length; and
fixing the substrate by the plurality of first stages.

17. The method of claim 16, wherein the second stroke length is nano scale or less.

18. The method of claim 16, wherein the fixing of the substrate includes:
providing a negative pressure to the plurality of first stages; and
adsorbing the substrate by the plurality of first stages.

19. The method of claim 18, wherein
the worktable system further includes a second stage disposed on the base stage to be spaced apart from the plurality of first stages, the second stage including a porous material, and
the method further includes planarizing the substrate after the adsorbing of the substrate.

20. The method of claim 19, wherein the planarizing of the substrate includes providing a positive pressure to the second stage.

21. The method of claim 16, wherein
the worktable system further includes a sensor spaced apart from the substrate in one of the extending directions of the substrate, the sensor that measures displacement of the substrate, and
after the adsorbing of the substrate, the method further includes:
measuring displacement of the substrate; and
changing a position of the substrate in case that the measuring displacement of the substrate is outside a selected range.
